(19) United States
(12) Patent Application Publication
(10) Pub. No.: US 2025/0309874 A1
(43) Pub. Date: Oct. 2, 2025

(54) PULSE AMPLITUDE MODULATION

(71) Applicant: Intel Corporation, Santa Clara, CA (US)

(72) Inventors: SreePraveen Nanduri, Bengaluru (IN); Sanjib Basu, Bangalore (IN); Mingming Xu, Phoenix, AZ (US); Vijayalakshmi Ramachandran, Chandler, AZ (US); Yinghong Jiang, Folsom, CA (US)

(21) Appl. No.: 18/616,647

(22) Filed: Mar. 26, 2024

(51) Int. Cl. H03K 5/02; H03K 17/687

(52) U.S. Cl. CPC H03K 5/02; H03K 17/6871

(57) ABSTRACT

An apparatus includes a plurality of sampler slicer circuits. At least one sampler slicer circuit of the plurality of sampler slicer circuits includes a plurality of transistor pairs. At least one transistor pair of the plurality of transistor pairs is to generate at least one output signal based on a tap signal. The sampler slicer circuit further includes a current source coupled to the transistor pair. The sampler slicer circuit further includes at least one transistor coupled to the transistor pair and the current source. The at least one transistor is to receive a control signal and perform an activation of the transistor pair based on the control signal.

### BACKGROUND

In most conventional high-speed input/output (HSIO) architecture designs, decision feedback equalizer (DFE) samplers and associated DFE taps are fixed by design. For example, for a half-rate bang-bang phase detector-based design, for each odd and even interleave, there will be one data sampler and one edge sampler plus associated fixed DFE tap switches. In the case of aging, over-stress, and excessive offset shift due to significant temperature changes, the link performance may drop significantly. A significant factor that affects the bit error rate (BER) of the link over time is the offset drift of the data samplers due to temperature shifts. Additionally, the BER can further deteriorate as the offset drift is calibrated infrequently, such as only during cold boot or rate changes.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of a slicer-based sampler and DFE switches architecture, in accordance with some embodiments;

FIG. 2 is a block diagram of a Y-slice data sampler and N-slice-based tap architecture, in accordance with some embodiments;

FIG. 3 is a block diagram of an example DFE architecture configured with slices from the FIG. 2 architecture, in accordance with some embodiments;

FIG. 4 is a flow diagram of an example method for calibrating a DFE, in accordance with some embodiments; and

FIG. 5 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

Existing DFE solutions include using parallel receiver (Rx) front-end architectures, using summer and a slicer as part of swapping, swapping the auxiliary slicer with a data sampler, and calibrating the data sampler offline after swapping.

However, these DFE solutions are associated with the following drawbacks. The drawback of having parallel Rx front-end architectures is mismatch and power-hungry solutions during swapping and does not ensure reliability and aging. The drawback of using summer and a slicer as part of swapping is that the summer and tap 1 are part of the swapping mechanism and cannot be used for voltage summer architectures. The DFE support can be speculative, not a 1UI closed loop half-rate DFE architecture. Swapping the auxiliary slicer can be associated with glitches during swapping and DFE tap feedback coupling for the swapped-out sampler.

The disclosed techniques include a slice-based sampler and DFE tap switches, which can be used to overcome the over-stress and excessive offset shift of existing DFE architectures by activating various slicers and extending the DFE lifetime. The disclosed DFE architecture can be used to overcome the above drawbacks of existing DFE architectures.

The disclosed techniques can be based on a sampler and DFE switches that are sliced into 1 to Y slicers (for the sampler) and 1 to N slicers (for the DFE taps), where Y and N can be selected based on the design. Those slicers of sampler and DFE taps can be activated (e.g., individually) to overcome aging, over-stress, and excessive offset shift and, therefore, prolong the lifetime of a product. In some aspects, Y and N can be selected as Y=N=3, and the slicers can be used to perform online calibration for temperature-induced offsets. Some advantages of the disclosed techniques include boosting link performance for a wide dynamic temperature range (DTR) without requesting link re-train while minimizing the disturbance to the data path to be 3 mV during sampler swapping.

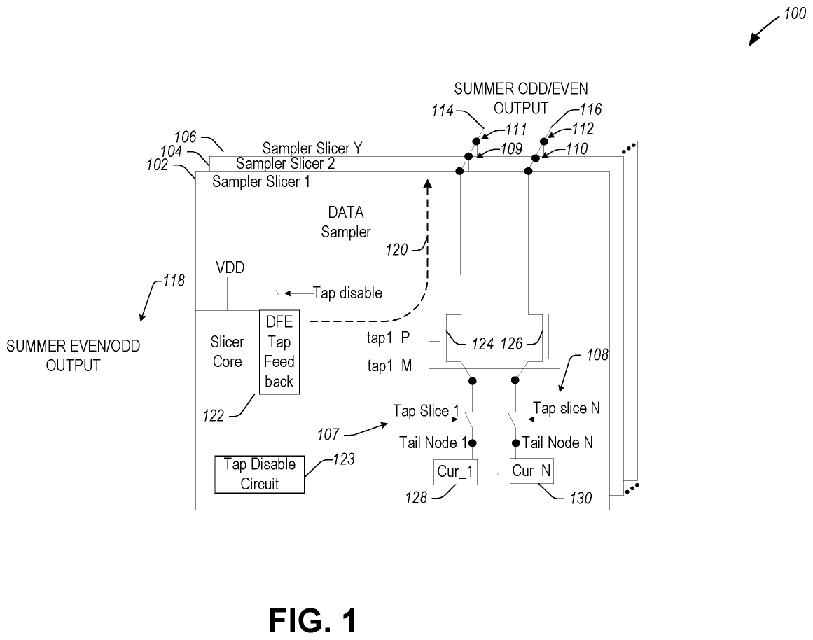

FIG. 1 is a block diagram of a slicer-based sampler and DFE switches architecture, in accordance with some embodiments. Referring to FIG. 1, the DFE architecture 100 includes sampler slicers 102, 104, . . . , 106, which are also referred to as sampler slicers 1, 2, . . . , Y. Each of the sampler slicers includes N DFE slicers. For example, sampler slicer 102 includes DFE slicers 107, . . . , 108, sampler slicer 104 includes DFE slicers 109, . . . , 110, and sampler slicer 106 includes DFE slicers 111, . . . , 112.

As illustrated in FIG. 1, the DFE slicers in the available sampler slicers are connected to each other and to the corresponding first feedback signal path 114 and a second feedback signal path 116.

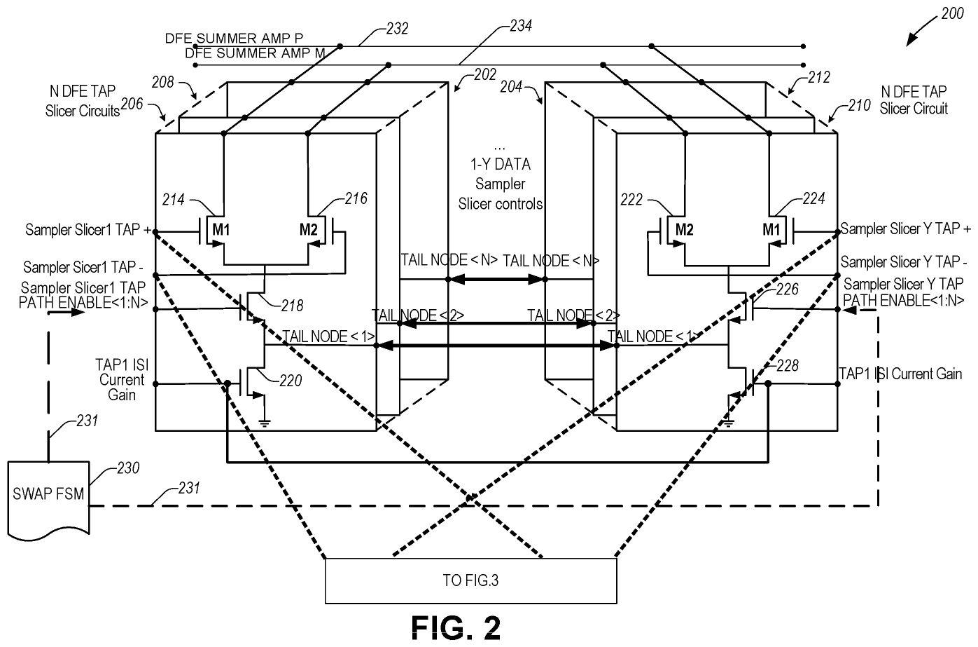

In some aspects, a sampler slicer (e.g., sampler slicer 102) receives summer output as an input signal 118. In some aspects, the tap disable circuit 123 can be used to activate or deactivate the particular sampler slicer (e.g., sampler slicer 102). In some aspects, the activation/deactivation of the sampler slicer can be based on a control signal (e.g., as illustrated in FIG. 2). Sampler slicer 102 further includes a tap feedback circuit 122 configured to generate differential tap signals (e.g., positive and negative tap signals) tap1_P and tap1_M that are supplied to the gates of transistors 124 and 126 used by the DFE slicers 107, . . . , 108.

DFE slicers 107, . . . , 108 include corresponding current sources 128, . . . , 130, tail nodes 1, . . . , N, tap slice switches 1, . . . , N, and transistors 124 and 126 (e.g., NMOS transistors). In operation, the differential tap signals generated by the tap feedback circuit 122 are processed in the feedback path 120 by the corresponding DFE slicer(s) and are output on the first feedback signal path 114 and the second feedback signal path 116.

In some aspects, the DFE architecture 100 splits the data sampler into 3 (Y) slicers as well as 3 DFE slicers (e.g., Y=N=3). This concept can be extended to any number of sampler slicers and DFE slicers. The focus of this split can be to calibrate the sampler offset induced by temperature shift in the mission mode. In some aspects, the slicer-based design can be extended to cover defects in the manufacturing process. Upon detection, the defective sampler slicer and DFE slicer can be disabled and replaced with other slicers. The disclosed DFE architectures can be used to prolong the lifetime of the products by detecting aged slicers and activating various slicers to replace aging or over-stressed ones.

In some aspects, the disclosed slicer-based techniques can be used to calibrate the offset of the DFE data slicers without affecting the link performance and maintain a sustainable link using pulse amplitude modulation with 3 levels (PAM3) signaling at a speed of 25.6 Gtps. The PAM3 system margins are in the range of 15 mV at a target BER of 1e-8 at a given boot condition. Without the proper solution, data sampler offset drift due to a wide range of temperature changes can consume all the margin the link has at initial boot and cause the link to have a bit error or a link downgrade.

In some aspects, the DFE architecture 100 of FIG. 1 can be used in a half-rate PAM3 architecture, where the RX data sampler is split into 3 (Y) slicers, together with the DFE tap1 also split into 3 (N) DFE slicers. At any given time, one of the sampler slicers and a DFE slicer combo can function as the most significant bit (MSB) slicer and MSB DFE tap1, and the other slicer can function as a least significant bit (LSB) slicer and LSB DFE tap1. The remaining sampler and DFE slicer can be used as a spare slicer to swap in or out the MSB/LSB slicer so that they can be taken offline for offset calibration during mission mode. The configured slicer can be swapped back after calibration. In this regard, the swapping using the disclosed techniques does not impact the link performance and is performed transparently to the link.

FIG. 2 is a block diagram of a Y-slice data sampler and N-slice-based tap architecture, in accordance with some embodiments. Referring to FIG. 2, DFE architecture includes sampler slicers 202, . . . , 204 (e.g., Y sampler slicers). Each sampler slicer can include multiple DFE slicers (e.g., N DFE slicers). For example, sampler slicer 202 includes DFE slicers 206, . . . , 208 (e.g., N DFE slicers), and sampler slicer 204 includes DFE slicers 210, . . . , 212 (e.g., N DFE slicers).

In some aspects, at least one of the DFE slicers can include a current source, a tail node (e.g., to connect to other DFE slicers in other sampler slicers), an enabling transistor, and a transistor pair for processing differential tap signals and outputting the processed tap signals to corresponding feedback signal paths (e.g., first feedback signal path 232 and second feedback signal path 234). For example, DFE slicer 206 of sampler slicer 202 includes transistor 220 (as the current source), enabling transistor 218, and transistor pair formed by transistors 214 and 216. Similarly, DFE slicer 210 of sampler slicer 204 includes transistor 228 (as the current source), enabling transistor 226, and transistor pair formed by transistors 222 and 224. The processing transistor in at least one transistor pair that receives the positive differential tap signal is designated in FIG. 2 as M1, and the processing transistor in at least one transistor pair that receives the negative differential tap signal is designated in FIG. 2 as M2.

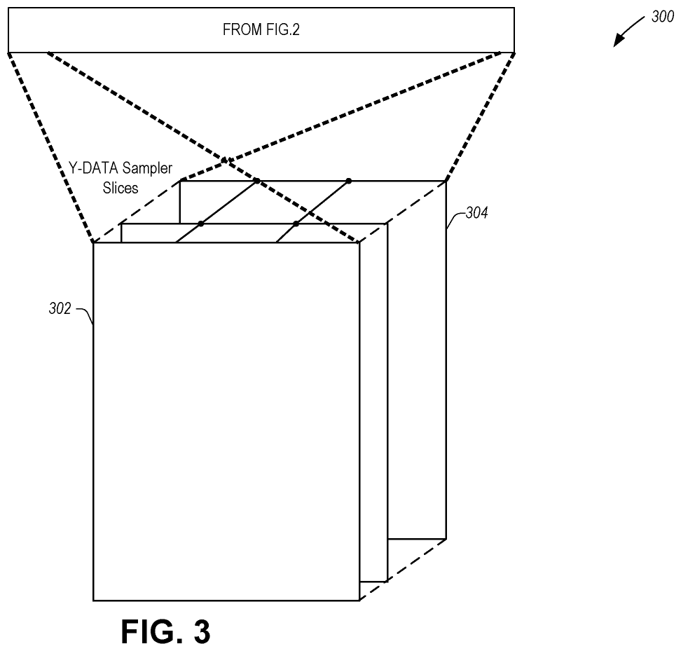

In some aspects, the selection of which sampler slicer and which DFE slicer to activate can be performed via control signals 231 communicated to each of the enabling transistors (e.g., enabling transistors 218 and 226 in FIG. 2). In some aspects, the control signals 231 can be generated based on a configuration such as a finite state machine (FSM) 230 or other techniques. An example DFE architecture 300 resulting from a selection using the FSM 230 is illustrated in FIG. 3.

FIG. 3 is a block diagram of an example DFE architecture configured with slices from the FIG. 2 architecture, in accordance with some embodiments. Referring to FIG. 3, DFE architecture 300 includes Y sampler slicers, such as sampler slicer 302 (based on sampler slicer 202 and DFE slicer 206), . . . , sampler slicer 304 (based on sampler slicer 204 and DFE slicer 210).

In some aspects, the swapping of the sampler slicers can be performed in such a way that there is minimal to no glitching or corruption on the summer output (e.g., the sampler slicer input), which might affect the BER. In a voltage summer architecture, DFE tap inter-signal interference (ISI) can be corrected by controlling the tail current of the tap structure, and the steering switches can be sized to carry the maximum current requirement of the ISI cancellation. During the swapping, a significant current may need to be steered from a sampler slicer X-controlled DFE tap switch to a sampler slicer Y-controlled tap switch. This may create significant glitches in summer output during swapping, thus impacting the link performance. This glitch can be significantly reduced with the disclosed DFE architectures using staggering activation/deactivation of sampler slicers. FSM 230 can be a digitally controlled state machine to control the tap switch so that at a given point of time, only a total of N or N+1 slices would be ON (e.g., as illustrated in FIG. 3). This ensures that the glitch injected during swapping scheme is small enough not to impact the BER.

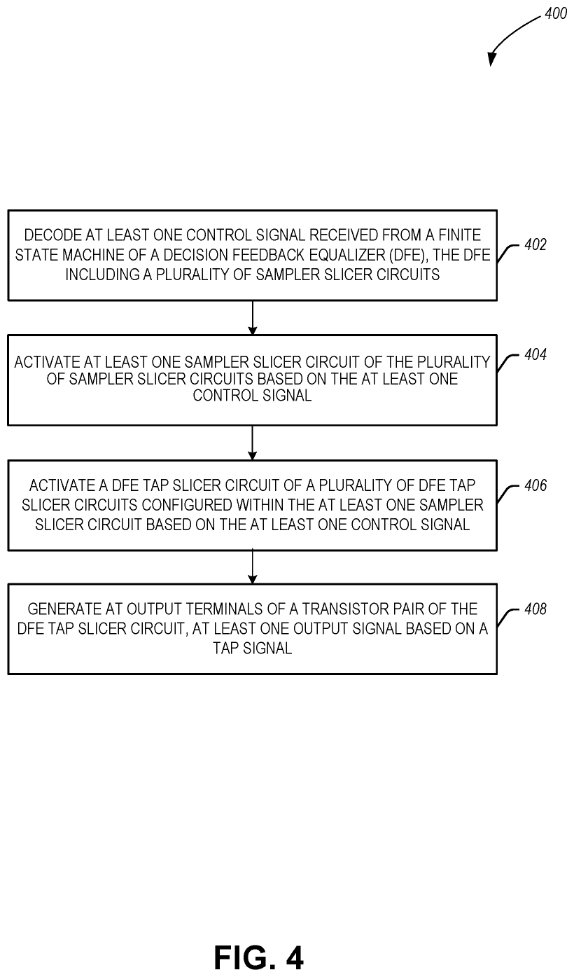

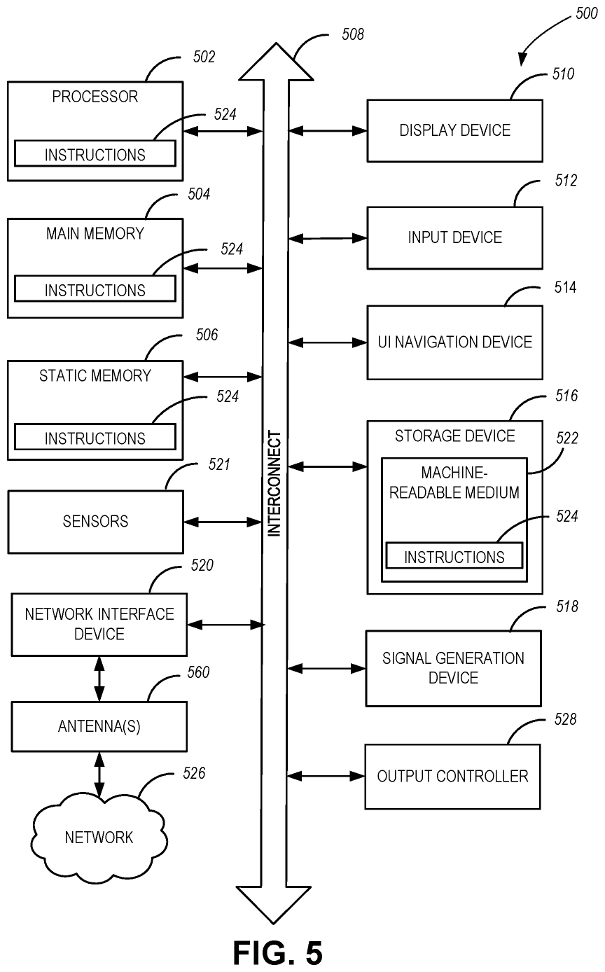

FIG. 4 is a flow diagram of an example method 400 for configuring a DFE, in accordance with some embodiments. Referring to FIG. 4, method 400 includes operations 402, 404, 406, and 408, which may be executed by an embedded controller or another processor of a computing device (e.g., hardware processor 502 of machine 500 illustrated in FIG. 5, which can include one or more of the circuits discussed in connection with FIGS. 1-3). In some embodiments, one or more of the circuits discussed in connection with FIGS. 1-3 can perform the functionalities listed in FIG. 4, as well as in the examples listed below.

At operation 402, at least one control signal (e.g., control signal 231) received from a finite state machine (e.g., FSM 230) of a decision feedback equalizer (DFE) (e.g., DFE architecture 200) is decoded. The DFE includes a plurality of sampler slicer circuits (e.g., sampler slicers 202, . . . , 204).

At operation 402, at least one sampler slicer circuit of the plurality of sampler slicer circuits is activated based on the at least one control signal (e.g., as discussed above in connection with FIG. 2 and FIG. 3).

At operation 404, a DFE tap slicer circuit of a plurality of DFE tap slicer circuits configured within the at least one sampler slicer circuit (e.g., one or more of DFE slicers 206, . . . , 208 in sampler slicer 202) is activated based on the at least one control signal.

At operation 406, at least one output signal is generated at output terminals of a transistor pair (e.g., transistors 214 and 216) of the DFE tap slicer circuit based on a tap signal.

FIG. 5 illustrates a block diagram of an example machine 500 upon which any one or more of the techniques (e.g., methodologies) discussed herein may perform. In alternative embodiments, the machine 500 may operate as a standalone device or may be connected (e.g., networked) to other machines. In a networked deployment, machine 500 may operate in the capacity of a server machine, a client machine, or both in server-client network environments. In an example, machine 500 may function as a peer machine in a peer-to-peer (P2P) (or other distributed) network environment. The machine 500 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 500 may include a hardware processor 502 (e.g., a central processing unit (CPU), a graphics processing unit (GPU), a hardware processor core, or any combination thereof), a main memory 504, and a static memory 506, some or all of which may communicate with each other via an interlink (e.g., bus) 508. In some aspects, the main memory 504, the static memory 506, or any other type of memory (including cache memory) used by machine 500 can be configured based on the disclosed techniques or can implement the disclosed memory devices.

Specific examples of main memory 504 include Random Access Memory (RAM) and semiconductor memory devices, which may include, in some embodiments, storage locations in semiconductors such as registers. Specific examples of static memory 506 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 500 may further include a display device 510, an input device 512 (e.g., a keyboard), and a user interface (UI) navigation device 514 (e.g., a mouse). In an example, the display device 510, the input device 512, and the UI navigation device 514 may be a touchscreen display. The machine 500 may additionally include a storage device (e.g., drive unit or another mass storage device) 516, a signal generation device 518 (e.g., a speaker), a network interface device 520, and one or more sensors 521, such as a global positioning system (GPS) sensor, compass, accelerometer, or other sensors. The machine 500 may include an output controller 528, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 502 and/or instructions 524 may comprise processing circuitry and/or transceiver circuitry.

The storage device 516 may include a machine-readable medium 522 on which one or more sets of data structures or instructions 524 (e.g., software) embodying or utilized by any one or more of the techniques or functions described herein can be stored. Instructions 524 may also reside, completely or at least partially, within the main memory 504, within static memory 506, or the hardware processor 502 during execution thereof by the machine 500. In an example, one or any combination of the hardware processor 502, the main memory 504, the static memory 506, or the storage device 516 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 522 is illustrated as a single medium, the term “machine-readable medium” may include a single medium or multiple media (e.g., a centralized or distributed database and/or associated caches and servers) configured to store instructions 524.

An apparatus of the machine 500 may be one or more of a hardware processor 502 (e.g., a central processing unit (CPU), a graphics processing unit (GPU), a hardware processor core, or any combination thereof), a main memory 504 and a static memory 506, one or more sensors 521, a network interface device 520, one or more antennas 560, a display device 510, an input device 512, a UI navigation device 514, a storage device 516, instructions 524, a signal generation device 518, and an output controller 528. The apparatus may be configured to perform one or more of the methods and/or operations disclosed herein. The apparatus may be intended as a component of machine 500 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 500 and that causes machine 500 to perform any one or more of the techniques of the present disclosure, or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 524 may further be transmitted or received over a communications network 526 using a transmission medium via the network interface device 520 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 520 may include one or more physical jacks (e.g., Ethernet, coaxial, or phone jacks) or one or more antennas to connect to the communications network 526. In an example, the network interface device 520 may include one or more antennas 560 to wirelessly communicate using at least one single-input multiple-output (SIMO), multiple-input multiple-output (MIMO), or multiple-input single-output (MISO) techniques. In some examples, the network interface device 520 may wirelessly communicate using multiple-user MIMO techniques. The term “transmission medium” shall be taken to include any intangible medium that can store, encode, or carry instructions for execution by the machine 500 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, at least one of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is a decision feedback equalizer (DFE) that includes a plurality of sampler slicer circuits, at least one sampler slicer circuit of the plurality of sampler slicer circuits includes a first N-channel metal-oxide semiconductor (NMOS) transistor, including a gate to receive a first input signal and a drain of the first NMOS transistor is coupled to a first feedback signal path; a second NMOS transistor including a gate to receive a second input signal, and a drain of the second NMOS transistor is coupled to a second feedback signal path; and a third NMOS transistor including a gate coupled to a current source, and a drain of the third NMOS transistor is coupled to a source of the first NMOS transistor and a source of the second NMOS transistor.

In Example 2, the subject matter of Example 1 includes subject matter where the sampler slicer circuit further includes a plurality of DFE tap slicer circuits, wherein a first DFE tap slicer circuit of the plurality of DFE tap slicer circuits includes the first NMOS transistor and the second NMOS transistor.

In Example 3, the subject matter of Example 2 includes subject matter where the drain of the first NMOS transistor is further coupled to a drain of a fourth NMOS transistor in at least a second DFE tap slicer circuit of the plurality of DFE tap slicer circuits.

In Example 4, the subject matter of Example 3 includes subject matter where the drain of the second NMOS transistor is further coupled to a drain of a fifth NMOS transistor in the at least a second DFE tap slicer circuit of the plurality of DFE tap slicer circuits.

In Example 5, the subject matter of Examples 1-4 includes a fourth NMOS transistor, wherein a drain of the fourth NMOS transistor is coupled to the source of the first NMOS transistor and the source of the second NMOS transistor.

In Example 6, the subject matter of Example 5 includes subject matter where a source of the fourth NMOS transistor is coupled to the drain of the third NMOS transistor.

In Example 7, the subject matter of Example 6 includes subject matter where the source of the fourth NMOS transistor is further coupled to a node of at least a second sampler slicer circuit of the plurality of sampler slicer circuits.

In Example 8, the subject matter of Examples 6-7 includes subject matter where a gate of the fourth NMOS transistor receives an enable signal to enable the sampler slicer circuit.

In Example 9, the subject matter of Examples 1-8 includes a processor, wherein the processor includes one or more of the first NMOS transistor, the second NMOS transistor, and the third NMOS transistor.

In Example 10, the subject matter of Examples 1-9 includes one or more interconnects coupling the first NMOS transistor, the second NMOS transistor, and the third NMOS transistor.

Example 11 is an apparatus that includes a plurality of sampler slicer circuits, at least one sampler slicer circuit of the plurality of sampler slicer circuits includes a plurality of transistor pairs, at least one transistor pair of the plurality of transistor pairs to generate at least one output signal based on a tap signal; a current source coupled to the transistor pair; and at least one transistor coupled to the transistor pair and the current source, the at least one transistor to receive a control signal and perform an activation of the transistor pair based on the control signal.

In Example 12, the subject matter of Example 11 includes subject matter where the sampler slicer circuit comprises a plurality of decision feedback equalizer (DFE) tap slicer circuits and wherein at least one DFE tap slicer circuit of the plurality of DFE tap slicer circuits includes a corresponding one of the plurality of transistor pairs.

In Example 13, the subject matter of Example 12 includes subject matter where at least one DFE tap slicer circuit of the plurality of DFE tap slicer circuits is coupled to at least one feedback signal path to receive the at least one output signal.

In Example 14, the subject matter of Examples 11-13 includes a finite state machine coupled to the plurality of sampler slicer circuits, the finite state machine to generate the control signal.

In Example 15, the subject matter of Examples 11-14 includes subject matter where the transistor pair comprises a first N-channel metal-oxide semiconductor (NMOS) transistor and a second NMOS transistor, and wherein a drain of the at least one transistor is coupled to a source of the first NMOS transistor and a source of the second NMOS transistor.

In Example 16, the subject matter of Example 15 includes subject matter where the first NMOS transistor is to generate a first output signal of the at least one output signal at a drain of the first NMOS transistor.

In Example 17, the subject matter of Examples 15-16 includes subject matter where the second NMOS transistor is to generate a second output signal of the at least one output signal at a drain of the second NMOS transistor.

Example 18 is a method that includes decoding at least one control signal received from a finite state machine of a decision feedback equalizer (DFE), the DFE including a plurality of sampler slicer circuits; activating at least one sampler slicer circuit of the plurality of sampler slicer circuits based on the at least one control signal; activating a DFE tap slicer circuit of a plurality of DFE tap slicer circuits configured within the at least one sampler slicer circuit based on the at least one control signal; and generating at output terminals of a transistor pair of the DFE tap slicer circuit, at least one output signal based on a tap signal.

In Example 19, the subject matter of Example 18 includes decoding a positive input signal component and a negative input signal component of the tap signal, wherein a first transistor of the transistor pair receives the positive input signal component and wherein a second transistor of the transistor pair receives the negative input signal component.

In Example 20, the subject matter of Example 19 includes supplying the at least one control signal and at least one current signal to at least one transistor of the DFE tap slicer circuit, the at least one transistor coupled to the transistor pair.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. A decision feedback equalizer (DFE) comprising:
a plurality of sampler slicer circuits, at least one sampler slicer circuit of the plurality of sampler slicer circuits comprising:
a first N-channel metal-oxide semiconductor (NMOS) transistor including a gate to receive a first input signal, and a drain of the first NMOS transistor is coupled to a first feedback signal path;
a second NMOS transistor including a gate to receive a second input signal, and a drain of the second NMOS transistor is coupled to a second feedback signal path; and
a third NMOS transistor including a gate coupled to a current source, and a drain of the third NMOS transistor is coupled to a source of the first NMOS transistor and a source of the second NMOS transistor.

2. The DFE of claim 1, wherein the sampler slicer circuit further comprises:
a plurality of DFE tap slicer circuits, wherein a first DFE tap slicer circuit of the plurality of DFE tap slicer circuits includes the first NMOS transistor and the second NMOS transistor.

3. The DFE of claim 2, wherein the drain of the first NMOS transistor is further coupled to a drain of a fourth NMOS transistor in at least a second DFE tap slicer circuit of the plurality of DFE tap slicer circuits.

4. The DFE of claim 3, wherein the drain of the second NMOS transistor is further coupled to a drain of a fifth NMOS transistor in the at least a second DFE tap slicer circuit of the plurality of DFE tap slicer circuits.

5. The DFE of claim 1, further comprising:
a fourth NMOS transistor, wherein a drain of the fourth NMOS transistor is coupled to the source of the first NMOS transistor and the source of the second NMOS transistor.

6. The DFE of claim 5, wherein a source of the fourth NMOS transistor is coupled to the drain of the third NMOS transistor.

7. The DFE of claim 6, wherein the source of the fourth NMOS transistor is further coupled to a node of at least a second sampler slicer circuit of the plurality of sampler slicer circuits.

8. The DFE of claim 6, wherein a gate of the fourth NMOS transistor receives an enable signal to enable the sampler slicer circuit.

9. The DFE of claim 1, further comprising a processor, and wherein the processor includes one or more of the first NMOS transistor, the second NMOS transistor, and the third NMOS transistor.

10. The DFE of claim 1, further comprising:
one or more interconnects coupling the first NMOS transistor, the second NMOS transistor, and the third NMOS transistor.

11. An apparatus comprising:
a plurality of sampler slicer circuits, at least one sampler slicer circuit of the plurality of sampler slicer circuits comprising:
a plurality of transistor pairs, at least one transistor pair of the plurality of transistor pairs to generate at least one output signal based on a tap signal;
a current source coupled to the transistor pair; and
at least one transistor coupled to the transistor pair and the current source, the transistor to receive a control signal and perform an activation of the transistor pair based on the control signal.

12. The apparatus of claim 11, wherein the sampler slicer circuit comprises a plurality of decision feedback equalizer (DFE) tap slicer circuits, and wherein at least one DFE tap slicer circuit of the plurality of DFE tap slicer circuits includes a corresponding one of the plurality of transistor pairs.

13. The apparatus of claim 12, wherein at least one DFE tap slicer circuit of the plurality of DFE tap slicer circuits is coupled to at least one feedback signal path to receive the at least one output signal.

14. The apparatus of claim 11, further comprising:
a finite state machine coupled to the plurality of sampler slicer circuits, the finite state machine to generate the control signal.

15. The apparatus of claim 11, wherein the transistor pair comprises a first N-channel metal-oxide semiconductor (NMOS) transistor and a second NMOS transistor, and wherein a drain of the at least one transistor is coupled to a source of the first NMOS transistor and a source of the second NMOS transistor.

16. The apparatus of claim 15, wherein the first NMOS transistor is to generate a first output signal of the at least one output signal at a drain of the first NMOS transistor.

17. The apparatus of claim 15, wherein the second NMOS transistor is to generate a second output signal of the at least one output signal at a drain of the second NMOS transistor.

18. A method comprising:
decoding at least one control signal received from a finite state machine of a decision feedback equalizer (DFE), the DFE including a plurality of sampler slicer circuits;
activating at least one sampler slicer circuit of the plurality of sampler slicer circuits based on the at least one control signal;
activating a DFE tap slicer circuit of a plurality of DFE tap slicer circuits configured within the at least one sampler slicer circuit based on the at least one control signal; and
generating at output terminals of a transistor pair of the DFE tap slicer circuit, at least one output signal based on a tap signal.

19. The method of claim 18, further comprising:
decoding a positive input signal components and a negative input signal component of the tap signal, wherein a first transistor of the transistor pair receives the positive input signal component, and wherein a second transistor of the transistor pair receives the negative input signal component.

20. The method of claim 19, further comprising:
supplying the at least one control signal and at least one current signal to at least one transistor of the DFE tap slicer circuit, the at least one transistor coupled to the transistor pair.
